(19) United States
(12) Patent Application Publication
(10) Pub. No.: US 2026/0327805 A1
(43) Pub. Date: Oct. 22, 2026

(54) THIN FILM DEPOSITION DEVICE

(71) Applicants: ACM RESEARCH (SHANGHAI), INC., Shanghai (CN); ACM Research Korea CO., LTD., Icheon-si (KR); CleanChip Technologies Limited, Hong Kong (CN)

(72) Inventors: Hui Wang, Shanghai (CN); Shan Zhang, Shanghai (CN); Tom Kim, Icheon-si (KR); Hongcai Fei, Shanghai (CN); William Baek, Icheon-si (KR); Jacob Lee, Icheon-si (KR); Xiaolin Ding, Shanghai (CN); Peilong Zhou, Shanghai (CN); Jun Wang, Shanghai (CN); Shena Jia, Shanghai (CN)

(73) Assignees: ACM RESEARCH (SHANGHAI), INC., Shanghai (CN); ACM Research Korea CO., LTD., Icheon-si (KR); CleanChip Technologies Limited, Hong Kong (CN)

(21) Appl. No.: 19/157,558

(22) PCT Filed: Jan. 30, 2024
(86) PCT No.: PCT/CN2024/074780

§ 371 Date: Aug. 18, 2025

(30) Foreign Application Priority Data
Feb. 17, 2023 (CN) 202310136405.7

(51) Int. Cl. C23C 16/458; C23C 16/46; C23C 16/505; C23C 16/52

(52) U.S. Cl. CPC C23C 16/4584; C23C 16/4586; C23C 16/46; C23C 16/505; C23C 16/52

(57) ABSTRACT

A thin film deposition device, comprising a controller (100) and a first-stage lifting mechanism (1), a second-stage lifting mechanism (2), a rotating mechanism (5), a supporting mechanism (3) and a heating mechanism (4) connected to the controller (100). The heating mechanism (4) comprises a heating tray (41) for heating a wafer (10). The first-stage lifting mechanism (1) is used for driving the second-stage lifting mechanism (2), the rotating mechanism (5), the supporting mechanism (3) and the heating mechanism (4) to synchronously ascend and descend to complete the first thin film deposition of the wafer (10). The supporting mechanism (3) comprises a guide ring (31) and a guide support shaft (34), and the guide support shaft (34) is connected to the guide ring (31). The second-stage lifting mechanism (2) is used for driving the guide ring (31) to ascend and descend, and enabling the guide ring (31) to be higher than the heating tray (41) when the guide ring (31) carries the wafer (10) to ascend. The rotating mechanism (5) is used for controlling the guide ring (31) to rotate, and the guide ring (31) is used for carrying the wafer (10) and driving the wafer (10) to rotate at a preset angle. The wafer (10) continues to carry out the second thin film deposition, and the device can repeatedly carry out the second thin film deposition step, thereby compensating for unevenness in the thickness of the thin film deposited on the wafer (10).

### FIELD OF THE INVENTION

The present invention relates to the technical field of semiconductor manufacturing equipment, and in particular to a thin film deposition device.

### BACKGROUND

PECVD refers to plasma enhanced chemical vapor deposition. In a vacuum process chamber of plasma enhanced chemical vapor deposition, a layer stack structure of different materials is deposited onto the wafer. Various dielectric thin films are deposited onto the surface of the wafer, and the thickness evenness of the thin film is one of the key parameters of the deposition process.

In actual production, uneven thickness of the thin film is easy to occur during thin film deposition, which leads to the failure of semiconductor device. The evenness of thin film directly affects the characteristic and yield of semiconductor device. How to effectively improve the evenness of thin film is an urgent problem to be solved at present.

### SUMMARY

In view of the above-described problem, an object of the present invention is to provide a thin film deposition device capable of optimizing the evenness problem caused by deviation of thin film thickness.

In order to achieve the above object, the present invention provides the following technical solutions:

A thin film deposition device, comprising:
a heating mechanism, including a heating tray, used to carry and heat a wafer;
a supporting mechanism, including a guide ring arranged around the heating tray and a guide support shaft connected to the guide ring;
a second-stage lifting mechanism, connected to the guide support shaft, used to drive the guide support shaft and the guide ring to ascend and descend, and enabling the guide ring to be higher than the heating tray when the guide ring carries the wafer to ascend;
a rotating mechanism, connected to the second-stage lifting mechanism, used to drive the guide ring to rotate through the second-stage lifting mechanism;
a first-stage lifting mechanism, carrying the second-stage lifting mechanism, the rotating mechanism and the heating mechanism, used to drive the rotating mechanism, the second-stage lifting mechanism and the heating mechanism to synchronously ascend and descend; and
a controller, used to control the first-stage lifting mechanism to drive the rotating mechanism, the second-stage lifting mechanism, the supporting mechanism and the heating mechanism to ascend synchronously in the first thin film deposition step, and making the heating tray and the guide ring ascend to the height of carrying the wafer; used to control the second-stage lifting mechanism to drive the guide ring to carry the wafer to continue to ascend to the height of carrying the wafer in the second thin film deposition step, and after the rotating mechanism is intermittently controlled to drive the guide ring and the wafer to rotate by a preset angle, controlling the second-stage lifting mechanism to drive the guide ring to descend to the height of the heating tray.

Compared with the prior art, the present invention has the following beneficial effects:

The thin film deposition device provided by the present invention comprises a first-stage lifting mechanism, a second-stage lifting mechanism, a rotating mechanism, a supporting mechanism and a heating mechanism. The heating mechanism comprises a heating tray. The supporting mechanism comprises a guide ring.

The device can realize two stages of lifting motion, namely the first-stage lifting motion and the second-stage lifting motion respectively. The first-stage lifting motion is used to realize the lifting and lowering of the first-stage platform and the parts thereon, that is, the first-stage lifting motion is used to make the second-stage lifting mechanism, the rotating mechanism, the supporting mechanism and the heating mechanism ascend to the process position and descend to the initial position. After reaching the process position, the heating tray heats the wafer, and the wafer completes the first thin film deposition.

The second-stage lifting motion is used to make the guide ring carry the wafer and continue to ascend. After that, the rotating mechanism drives the guide ring to carry the wafer to rotate by the preset angle. After the wafer is rotated by the preset angle, the wafer stops rotating. The second-stage lifting motion drives the guide ring to descend to the process position, the heating tray heats the wafer, the plasma gas carries out the thin film deposition on the wafer, and the wafer completes the second thin film deposition. The second thin film deposition step may be repeated according to the case where the thin film is deposited, thereby compensating for unevenness in the thickness of the thin film deposited on the wafer.

### BRIEF DESCRIPTION OF THE DRAWINGS

In order to more clearly explain the embodiments of the present invention or the technical solutions in the prior art, the drawings that need to be used in the description of the embodiments or the prior art will be briefly introduced below. And it is obvious that the drawings in the following description are only some embodiments of the present invention, and for those of ordinary skill in the art, other drawings can be obtained according to these drawings without making creative labor.

FIG. 1(a) is a perspective schematic view of an entire thin film deposition device according to the first embodiment of the present invention.

FIG. 1(b) is a perspective schematic view of a thin film deposition device without a process chamber according to the first embodiment of the present invention.

FIG. 2 is a partial structural side view of a thin film deposition device comprising a first-stage lifting mechanism according to the first embodiment of the present invention.

FIG. 3 is a partial cross-sectional schematic view of the partial structure of a thin film deposition device comprising a first-stage lifting mechanism according to the first embodiment of the present invention.

FIG. 4 is a partial structural cross-sectional view of a thin film deposition device comprising a first-stage lifting mechanism according to the first embodiment of the present invention.

FIG. 5(a) to 5(b) are perspective schematic views of the partial structure of a thin film deposition device comprising a second-stage lifting mechanism according to the first embodiment of the present invention, wherein FIG. 5(a) is a non-lifting state, and FIG. 5(b) is a lifting state.

FIG. 6 is a partial cross-sectional view of a thin film deposition device comprising a rotating mechanism according to the first embodiment of the present invention.

FIG. 7(a) to 7(c) are schematic views of various states in the process flow of a thin film deposition device according to the first embodiment of the present invention.

FIG. 7(d) is a partially enlarged schematic view of FIG. 7(a).

FIG. 8 is a schematic view of a heating tray and a tray shaft according to the first embodiment of the present invention.

FIG. 9 is a partially enlarged cross-sectional view of position A in FIG. 8.

FIG. 10 is a partially enlarged cross-sectional view of position B in FIG. 8.

FIG. 11(a) to 11(d) respectively illustrate schematic views of different preset angles of wafer rotation according to the present invention.

FIG. 12 is a partially enlarged schematic view of a thin film deposition device according to the first embodiment of the present invention.

FIG. 13 is a schematic view of a thin film deposition device according to the second embodiment of the present invention.

FIG. 14 is a first schematic view of a thin film deposition device according to the third embodiment of the present invention.

FIG. 15 is a second schematic view of a thin film deposition device according to the third embodiment of the present invention.

FIG. 16 shows a connection relationship between a controller and various components according to the present invention.

### PREFERRED EMBODIMENTS OF THE INVENTION

In order to make the objects, features and advantages of the present invention more obvious and easier to understand, the technical solutions in the embodiments of the present invention will be clearly and completely described below with reference to the accompanying drawings in the embodiments of the present invention. And it is obvious that the embodiments described below are only some embodiments of the present invention, but not all embodiments. Based on the embodiments in the present invention, all other embodiments obtained by those of ordinary skill in the art without making creative effort fall within the scope of protection of the present invention.

In the description of the present invention, it is to be understood that when one component is considered to be “connected” to the other component, it may be directly connected to the other component or there may be components disposed in the center at the same time. When a component is considered to be “disposed” on the other component, it may be a component disposed directly on the other component or there may be components disposed in the center at the same time.

Hereinafter, the technical solutions of the present invention will be further described with reference to the accompanying drawings and specific embodiments.

### Embodiment 1

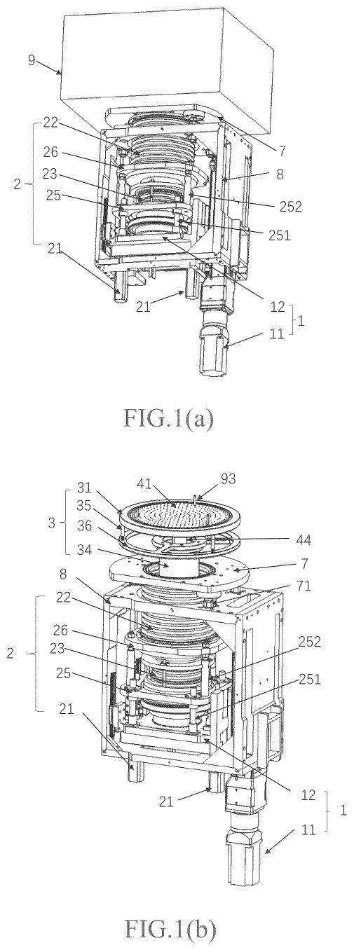

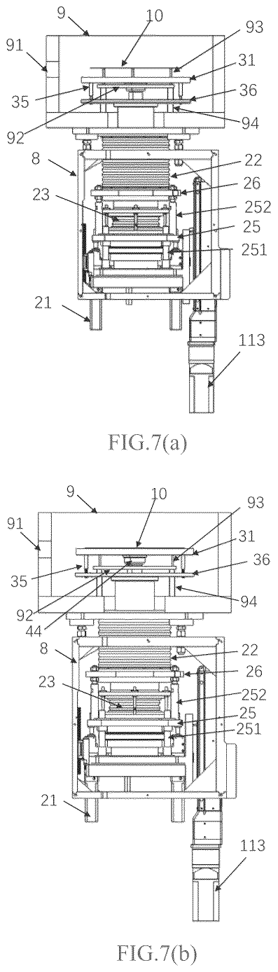

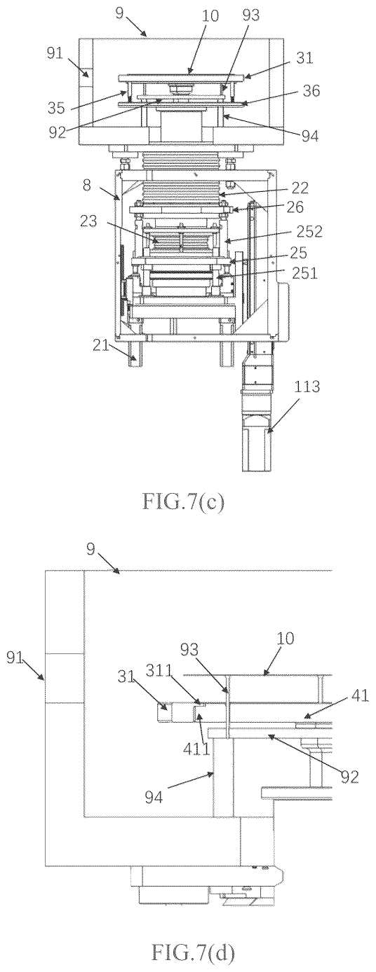

Referring to FIG. 1(a) and 1(b), the present embodiment provides a thin film deposition device having a process chamber platform 7, an outer frame 8 and a process chamber 9 mounted on a base (not shown). During the work of the device, the process chamber 9 is fixed. The process chamber platform 7 is connected to the outer frame 8, and the process chamber 9 is fixedly connected to the process chamber platform 7. For example, the process chamber platform 7 is connected to and supported above the outer frame 8 by a plurality of connectors 71. Referring to FIG. 7(a), the process chamber 9 has an openable and closable chamber door 91. In the process chamber 9, a heating mechanism 4 and a supporting mechanism 3 are arranged. The heating mechanism 4 comprises a heating tray 41 and a tray shaft 44. The heating tray 41 is used for carrying and heating the wafer 10. One end (the upper end in the figure) of the tray shaft 44 is provided on the heating tray 41 to support the heating tray 41, and the other end extends downward through the process chamber 9 and the process chamber platform 7. The inside of the process chamber 9 comprises a counterweight plate 92, thimbles 93 and support columns 94. The bottom portions of a plurality of thimbles 93 (three shown in the figure) are arranged on the counterweight plate 92, the counterweight plate 92 is overlapped by gravity on the support columns 94, and the support columns 94 are fixed to the bottom of the process chamber 9. The plurality of thimbles 93 are used to carry the wafer 10. Referring to FIG. 7(d), the heating tray 41 is provided with accommodation holes, and thimbles 93 pass through the accommodation holes and are movable up and down in the accommodation holes.

The supporting mechanism 3 comprises a guide ring 31, a guide support shaft 34, connecting rods 35 and a guide ring platform 36. The guide ring 31 is disposed around the heating tray 41, but can move relative to the heating tray 41. The guide ring 31 overlaps the heating tray 41 by gravity. The guide ring platform 36 is located below the guide ring 31, and a plurality of connecting rods 35 are arranged between the guide ring platform 36 and the guide ring 31. The connecting rods 35 are arranged below the guide ring 31, and a certain distance is maintained between the connecting rods 35 and the guide ring 31. When the connecting rods 35 are driven to move upward alone, the connecting rods 35 can overlap with the guide ring 31 and drive the guide ring 31 to move upward. One end of the guide support shaft 34 (the upper end in the figure) is connected to the guide ring platform 36, and the other end extends downward through the process chamber 9 and the process chamber platform 7. The tray shaft 44 is sleeved within the guide support shaft 34. Alternatively, aluminum oxide is selected for the guide ring 31. In some embodiments, the guide ring platform 36 and the connecting rods 35 may be omitted, and the guide ring 31 may be directly connected to the guide support shaft 34. In some embodiments, the connecting rods 35 are directly connected to the guide ring 31, and the guide ring 31 is always separated from the heating tray 41.

The first-stage lifting mechanism 1 is arranged on the outer frame 8, and the first-stage lifting mechanism 1 carries the second-stage lifting mechanism 2, the supporting mechanism 3 and the heating mechanism 4 (specifically, the tray shaft 44), and is used for driving these mechanisms to ascend and descend synchronously. During the lifting process, the heating tray 41 and the guide ring 31 ascend accordingly and reach the height of the top of the thimbles 93. The heating tray 41 drives the counterweight plate 92 and the thimbles 93 to ascend, and the counterweight plate 92 and the support columns 94 are separated. The thimbles 93 are light in weight and are completely retracted into the accommodation holes depending on the weight of the counterweight plate 92. The heating tray 41 and the guide ring 31 carry the wafer 10, which ensures that the upper surface of the heating tray 41 in contact with the wafer 10 is flat, and the heating tray 41 heats the wafer 10. The second-stage lifting mechanism 2 is connected to the guide support shaft 34 for driving the guide support shaft 34 and the connecting rods 35 to ascend and descend, and the connecting rods 35 carry the guide ring 31 to ascend and make the guide ring 31 gradually higher than the heating tray 41 when carrying the wafer 10 to ascend. The rotating mechanism 5 is connected to the second-stage lifting mechanism 2, and is used for driving the guide ring 31 to rotate by the preset angle through the second-stage lifting mechanism 2.

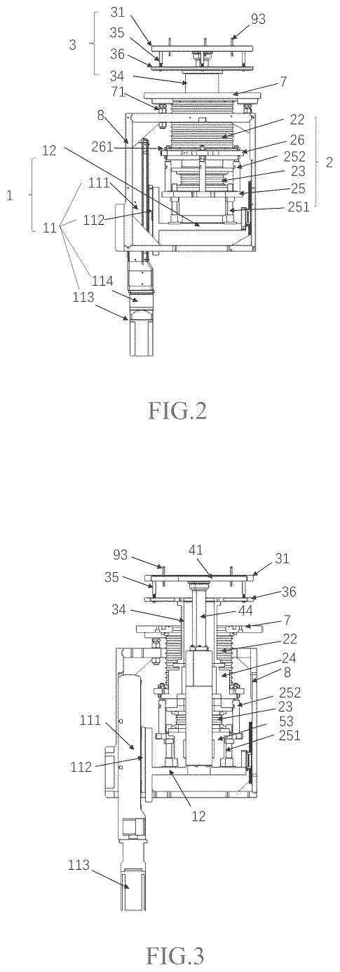

Referring continuously to FIGS. 2-4, the first-stage lifting mechanism 1 comprises a first-stage driving unit 11 and a first-stage platform 12.

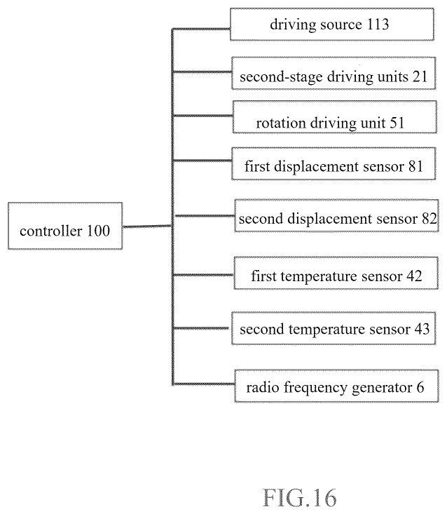

The first-stage driving unit 11 comprises a linear module 111, a slider 112 and a driving source 113. The driving source 113 may be a servo motor. The slider 112 is movably mounted on the linear module 111, and the first-stage platform 12 is mounted on the slider 112. The linear module 111 is provided on the outer frame 8, and the driving source 113 is connected to the linear module 111. Referring to FIG. 16, the driving source 113 is connected to the controller 100, and the controller 100 controls the driving source 113 to work.

In one embodiment, the first-stage driving unit 11 further comprises a speed reducer 114 additionally provided between the driving source 113 and the linear module 111, so as to reduce the load rate of the driving source 113 and improve the operational stability of the first-stage driving unit 11.

The first-stage platform 12 is used for carrying the second-stage lifting mechanism 2, the rotating mechanism 5 and the heating mechanism 4. The supporting mechanism 3 is arranged on the second-stage lifting mechanism 2. Specifically, the tray shaft 44 of the heating mechanism 4 is connected to the first-stage platform 12, and the relationship of the other mechanisms to the first-stage platform 12 will be described later.

Referring to FIG. 1(a), 1(b), 4 and 5(a) at the same time, the second-stage lifting mechanism 2 comprises second-stage driving units 21, an upper bellows 22, a lower bellows 23, an upper magnetic fluid 24, a second-stage lower platform 25, a second-stage upper platform 26, a first flange 27, a second flange 28 and a third flange 29. The second-stage driving units 21 are connected to the controller 100. The second-stage lower platform 25 is disposed on the first-stage platform 12 by a plurality of first support members 251. The second-stage upper platform 26 is disposed on the second-stage lower platform 25 by a plurality of second support members 252 disposed on the second-stage platform 25. The lower end of the upper bellows 22 is fixed to the second-stage upper platform 26. The upper end of the upper bellows 22 is fixed to the process chamber platform 7, so that the upper end of the upper bellows 22 is fixed during the work of the device. The upper magnetic fluid 24 is disposed on the second-stage upper platform 26 and sleeved within the upper bellows 22 and surrounds the tray shaft 44. The upper magnetic fluid 24 is respectively connected to the lower end of the guide support shaft 34 and the lower end of the upper bellows 22, so as to ascend together with the lower end of the upper bellows 22 and drive the guide support shaft 34 and the guide ring 31 to ascend. The upper end of the lower bellows 23 is connected to the upper magnetic fluid 24 through the first flange 27, and the lower end of the lower bellows 23 is connected to the rotating mechanism 5 through the second flange 28.

The second-stage driving units 21 are used to drive the second-stage lower platform 25 to ascend. Optionally, the second-stage driving units 21 are provided on the first-stage platform 12, comprising lead screws 211 passing through the second-stage lower platform 25, and the second-stage lower platform 25 moves up and down along the lead screws 211.

Furthermore, the upper magnetic fluid 24 comprises an upper magnetic fluid inner shaft 241 and an upper magnetic fluid outer ring 242, and the upper magnetic fluid outer ring 242 is sleeved at the outer periphery of the upper magnetic fluid inner shaft 241. The upper end of the upper magnetic fluid inner shaft 241 is connected to the guide support shaft 34. The upper magnetic fluid outer ring 242 and the lower end of the upper bellows 22 are connected by the third flange 29. Optionally, the upper end of the upper magnetic fluid inner shaft 241 and the guide support shaft 34 are connected directly or by a connector. The upper end of the lower bellows 23 and the lower end of the upper magnetic fluid inner shaft 241 are connected by the first flange 27.

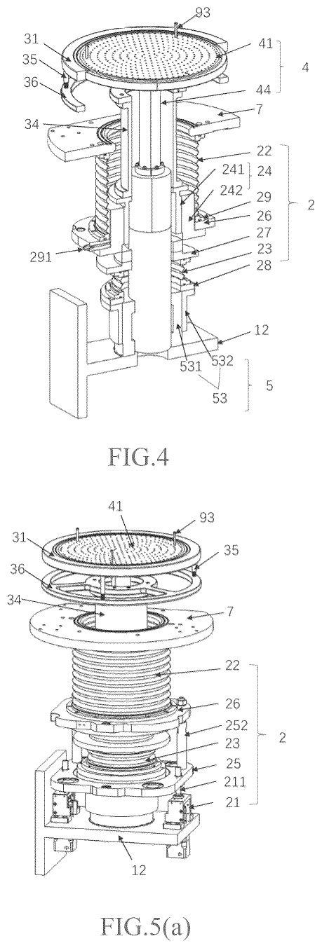

Referring to FIGS. 4 and 6 at the same time, the rotating mechanism 5 comprises a rotation driving unit 51, a pulley 52 and a lower magnetic fluid 53. The rotation driving unit 51 is connected to the controller 100. The rotation driving unit 51 is used to drive the pulley 52 to rotate. The lower magnetic fluid 53 comprises a lower magnetic fluid inner shaft 531 and a lower magnetic fluid outer ring 532, and the lower magnetic fluid outer ring 532 is sleeved at the outer periphery of the lower magnetic fluid inner shaft 531. The lower end of the lower bellows 23 and the lower magnetic fluid outer ring 532 are connected by the second flange 28. The lower magnetic fluid inner shaft 531 is connected to the first platform 12. The pulley 52 is sleeved at the outer periphery of the lower magnetic fluid outer ring 532, and the lower magnetic fluid outer ring 532, the lower bellows 23, the upper magnetic fluid inner shaft 241, the guide support shaft 34 and the guide ring 31 rotate together with the pulley 52. Optionally, the rotation driving unit 51 may select a motor as the power source.

The work process of the thin film deposition device is described below with reference to FIG. 7(a)-7(d).

In FIG. 7(a), the chamber door 91 of the process chamber 9 is opened, and a manipulator (not shown) carries the wafer 10 into the process chamber 9 from the chamber door 91 and is placed on the thimbles 93. At this time, the first-stage lifting mechanism 1 and the second-stage lifting mechanism 2 have not yet worked, and the heating tray 41 and the guide ring 31 are both in the initial position. The guide ring 31 is overlapped on the heating tray 41, the heating tray 41 and the guide ring 31 have the same height, and the thimbles 93 are in the accommodation holes of the heating tray 41. Referring to FIG. 7(d), the first protrusion 311 of the guide ring 31 is overlapped on the second protrusion 411 of the heating tray 41.

In FIG. 7(b), the first-stage lifting mechanism 1 works, the first-stage driving unit 11 drives the first-stage platform 12 to ascend, and the tray shaft 44 carries the heating tray 41 and the guide ring 31 to ascend together with the first-stage platform 12. When the first-stage platform 12 moves, the first-stage platform 12 drives the second-stage lower platform 25 and the second-stage upper platform 26 to ascend together. The lower end of the upper bellows 22 ascends together with the second-stage upper platform 26, and the lower end of the upper bellows 22 drives the upper magnetic fluid 24, the guide support shaft 34 and the connecting rods 35 to ascend. That is, the first-stage lifting mechanism drives the heating tray 41 and the guide ring 31 to jointly ascend to the process position. In this process position, the guide ring 31 and the heating tray 41 both carry the wafer 10, the heating tray 41 heats the wafer 10, and the heating tray 41 transfers part of the heat to the guide ring 31 by the method of heat conduction. The edge of the wafer 10 carried by the guide ring 31 is also heated, and then the plasma gas performs thin film deposition on the wafer 10, and the wafer 10 completes the first thin film deposition. In this first thin film deposition step, the rotating mechanism 5 also ascends together with the first-stage platform 12.

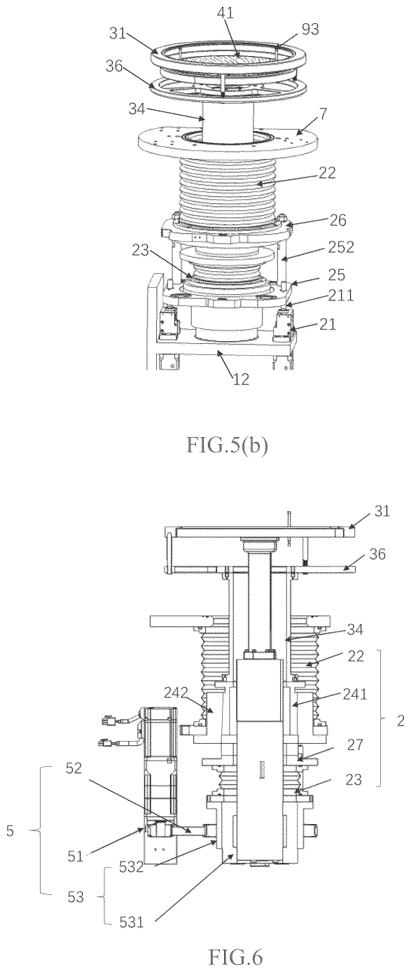

The following is the second thin film deposition step. Refer to FIG. 5(b) and FIG. 7(c), when the second-stage lifting mechanism 2 works, the second-stage driving units 21 drive the second-stage lower platform 25 to ascend, and the second-stage lower platform 25 drives the second-stage upper platform 26 to ascend. The lower end of the upper bellows 22 continues to ascend with the second-stage upper platform 26, and the upper bellows 22 continues to be compressed by the second-stage upper platform 26. During the period that the lower end of the upper bellows 22 ascends, the upper magnetic fluid 24 ascends together with the lower end of the upper bellows 22, and the upper magnetic fluid 24 drives the guide support shaft 34 and the connecting rods 35 to ascend. When the connecting rods 35 move upward, the connecting rods 35 overlap with the guide ring 31 and support the guide ring 31 to move upward, so that the height of the guide ring 31 gradually exceeds the height of the heating tray 41 and carries the wafer 10 alone. The guide ring 31 ascends to the rotational position. In this process, the upper end of the lower bellows 23 ascends together with the upper magnetic fluid inner shaft 241, and the lower bellows 23 is in an elongated state.

Referring to FIG. 6, then the rotating mechanism 5 works, and the rotation driving unit 51 drives the pulley 52 to rotate, and the pulley 52 drives the lower magnetic fluid outer ring 532 to rotate. The lower bellows 23 and the upper magnetic fluid inner shaft 241 rotate together with the lower magnetic fluid outer ring 532, thereby driving the guide support shaft 34 and the guide ring 31 to rotate. The guide ring 31 carries the wafer 10 (see FIG. 7(c)) to rotate by the preset angle. After the guide ring 31 is rotated by the preset angle, the guide ring 31 stops rotating.

Then, the second-stage lifting mechanism 2 continues to work and drives the guide support shaft 34 and the guide ring 31 to descend. The guide ring 31 carries the wafer 10 to descend to the process position again, and the wafer 10 is placed on the heating tray 41. The guide ring 31 is overlapped on the heating tray 41, and returns to the working state of FIG. 7(b) to carry out the second thin film deposition.

According to the deposition situation of the wafer 10, the second thin film deposition step may be repeated, and the wafer 10 may be deposited multiple times.

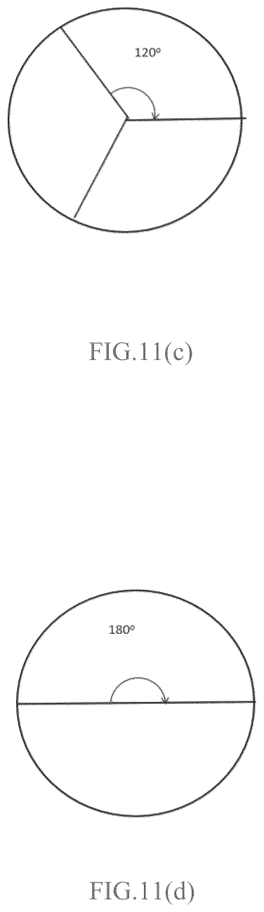

Referring to FIG. 11(a)-11(d), after the first thin film deposition is completed, (number of wafer rotations +1)*preset angle of each wafer rotation=360°. In this embodiment, as shown in the figure, after the first thin film deposition is completed, the number of rotations of the wafer 10 is 5 times, and the preset angle of each rotation is 60 degrees; Besides, the number of rotations of the wafer 10 is three times, and the preset angle of each rotation is 90 degrees; Besides, the number of rotations of the wafer 10 is twice, and the preset angle of each rotation is 120 degrees; The number of rotations of the wafer 10 is once, and the preset angle of each rotation is 180 degrees. The thin film deposition device of the present application can realize two stages of lifting motion, namely, a first-stage lifting motion and a second-stage lifting motion, respectively. The first-stage lifting motion is used to achieve the lifting and lowering of the first-stage platform 12 and the components thereon, i.e., for ascending the second-stage lifting mechanism 2, the rotating mechanism 5, the supporting mechanism 3 and the heating mechanism 4 to the process position and descending to the initial position. The second-stage lifting motion is used to make the guide ring 31 exceed the heating tray 41 in height, the guide ring 31 carries the wafer 10 to ascend, and then the guide ring 31 carries the wafer 10 to rotate by the preset angle. The device can realize at least two thin film depositions, thereby compensating for unevenness in the thickness of the thin film deposited on the wafer 10.

Furthermore, when the first-stage driving unit 11 drives the first-stage platform 12 to descend, the upper bellows 22 is elongated or restored to a natural shape, and the second-stage lifting mechanism 2, the rotating mechanism 5, the supporting mechanism 3 and the heating mechanism 4 all descend to the initial position.

Furthermore, the device also comprises a first displacement sensor 81 and a second displacement sensor 82 (refer to FIG. 16), both of the first displacement sensor 81 and the second displacement sensor 82 are connected to the controller 100 and arranged on the outer frame 8. The first displacement sensor 81 is used to monitor the moving distance of the first-stage platform 12, and the second displacement sensor 82 is used to monitor the moving distance of the second-stage platform 25. The controller 100 accurately controls the moving distance of the first-stage platform 12 and the second-stage lower platform 25 according to the moving data monitored by the two displacement sensors.

In the process of thin film deposition, some plasma gas will remain on the inner wall of the process chamber 9. A first gap is between the tray shaft 44 and the upper magnetic fluid 24, and a second gap is between the tray shaft 44 and the guide support shaft 34. Referring to FIG. 4, in an alternative embodiment, through holes are provided in both the third flange 29 and the upper magnetic fluid 24, and an N2 gas source interface 291 is provided on the third flange 29. The N2 gas source is blown into the first gap and flows upward to the second gap through the N2 gas source interface 291 and the through holes sequentially, and is discharged from the port of the guide support shaft 34, thereby carrying out the residue in the process chamber 9 to the outside of the process chamber 9.

In order to further improve the evenness of thin film deposition, it is necessary to ensure the levelness of the heating tray 41 when the device works. In an alternative embodiment, the four connectors 71 on the process chamber platform 7 are first adjusting members, one ends of the first adjusting members are connected to the bottom of the process chamber platform 7, and the other ends of the first adjusting members are connected to the outer frame 8. The first adjusting members may be bolts. A level recorder is placed on the heating tray 41, and the level recorder is used to measure the level degree of the heating tray 41. The vertical side of the outer frame 8 is perpendicular to the first platform 12, the tray shaft 44 is vertically disposed on the first platform 12, and the heating tray 41 and the tray shaft 44 are in a vertical state. By adjusting the positions of the connectors 71 according to the value of the level recorder to adjust the levelness of the outer frame 8, the level of the upper surface of the heating tray 41 can be accurately controlled, and the evenness of thin film deposition can be reliably guaranteed.

In the present application, the second-stage upper platform 26 is provided with a second adjusting member 261 (see FIG. 2). Optionally, the second adjusting member 261 is a nut. Specifically, the guide support shaft 34 is connected to the second-stage upper platform 26 by the upper magnetic fluid 24. The upper parts of the second support members 252 comprise a threaded segment, and the nut is adjusted at the position of the upper ends of the second support members 252, so that the second-stage lower platform 25 and the second-stage upper platform 26 are parallel. The guide support shaft 34 and the second-stage upper platform 26 are vertical, so as to accurately control the horizontal position and the upper surface level of the guide ring 31, thereby realizing the concentricity of the guide ring 31 with the heating tray 41 by adjusting the guide ring 31.

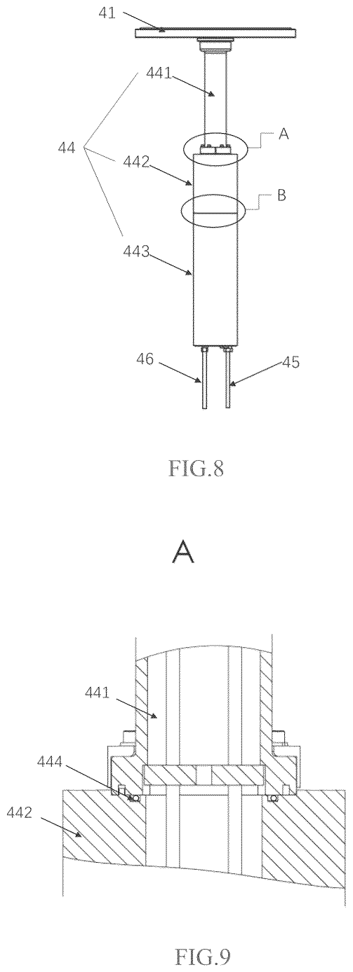

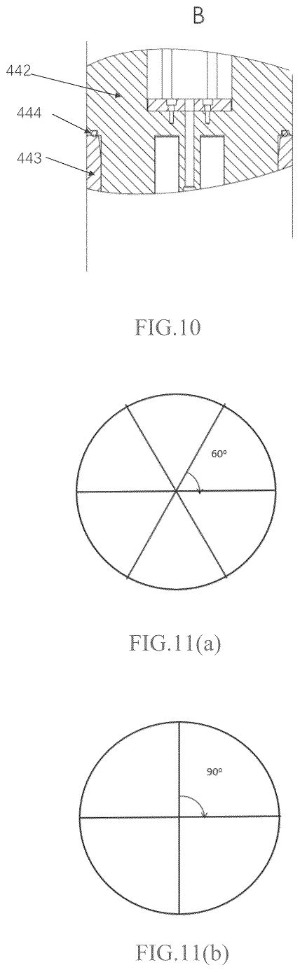

Referring to FIGS. 8-10, in an alternative embodiment, the tray shaft 44 comprises a basic shaft 441, a fixed seat 442 and adapter shafts 443. An upper end of the basic shaft 441 is connected to the heating tray 41, and both ends of the fixed seat 442 are connected to the lower end of the basic shaft 441 and the upper end of the adapter shafts 443 respectively. The lower ends of the adapter shafts 443 are connected to the first platform 12. Seal rings 444 are provided at a connection between the fixed seat 442 and the basic shaft 441 and at the connection between the fixed seat 442 and the adapter shafts 443. In actual production, the seal rings 444 are susceptible to thermal aging and the lives are reduced, and the seal rings 444 are not easily replaced in the device. In order to extend the service lives of the seal rings 444, in an alternative embodiment, the inner cavities of the adapter shafts 443 and the fixed seat 442 are provided with a liquid inlet pipe 46 and a liquid outlet pipe 45. The coolant introduced from the outside enters the inner cavities of the adapter shafts 443 and the fixed seat 442 through the liquid inlet pipe 46 and flows out of the liquid outlet pipe 45, so as to cool the seal rings 444.

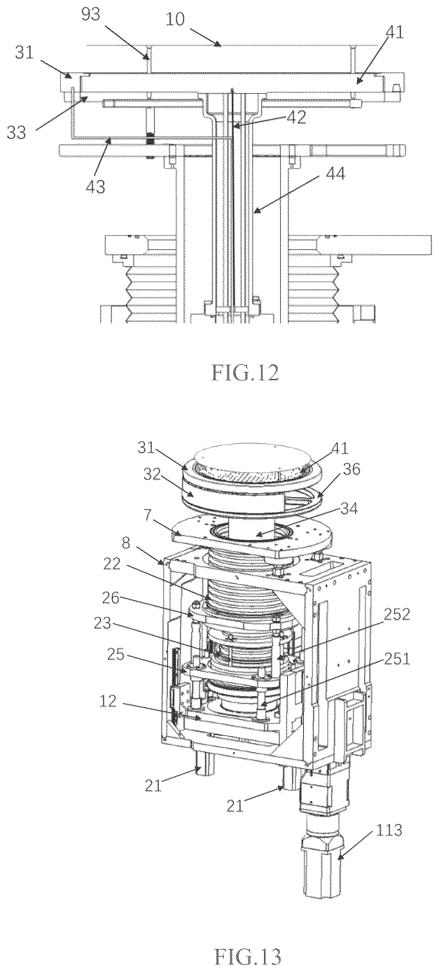

Referring to FIGS. 12 and 16, the heating mechanism 4 further comprises a first temperature sensor 42, and the first temperature sensor 42 is connected to the controller 100. The first temperature sensor 42 is disposed in the inner cavity of the tray shaft 44, the end portion of the first temperature sensor 42 is inserted into the inside of the heating tray 41. The first temperature sensor 42 is used to measure the temperature value of the heating tray 41 and transmit the temperature value to the controller 100, and the controller 100 controls the work of the heating tray 41 according to the temperature value, thereby further improving the evenness in the thickness of the thin film deposited on the wafer 10.

In an alternative embodiment, the supporting mechanism 3 further comprises a heating plate 33 disposed below the guide ring 31, the heating plate 33 has the same shape as the guide ring 31, and the heating plate 33 is used for heating the guide ring 31. At this time, the heating tray 41 is equivalent to the inner heating tray, and the guide ring 31 is equivalent to the outer heating tray, and the temperature difference between the edge region and the center region of the wafer 10 is compensated, so that the temperature of the center region and the edge region of the wafer 10 is kept consistent. The entire wafer 10 is heated uniformly, effectively improving the evenness in the thickness of the thin film deposited on the wafer 10.

Furthermore, the heating mechanism 4 further comprises a second temperature sensor 43 provided on the guide ring 31, and the second temperature sensor 43 is connected to the controller 100. The second temperature sensor 43 measures the temperature of the guide ring 31 and feeds the temperature back to the controller 100. The controller 100 controls the work of the heating plate 33 according to the numerical values of the first temperature sensor 42 and the second temperature sensor 43, so that the guide ring 31 is consistent with the temperature of the heating tray 41, thereby achieving evenness of the overall surface temperature of the wafer 10. Alternatively, the material of the guide ring 31 is aluminum nitride having fast heat conduction.

### Embodiment 2

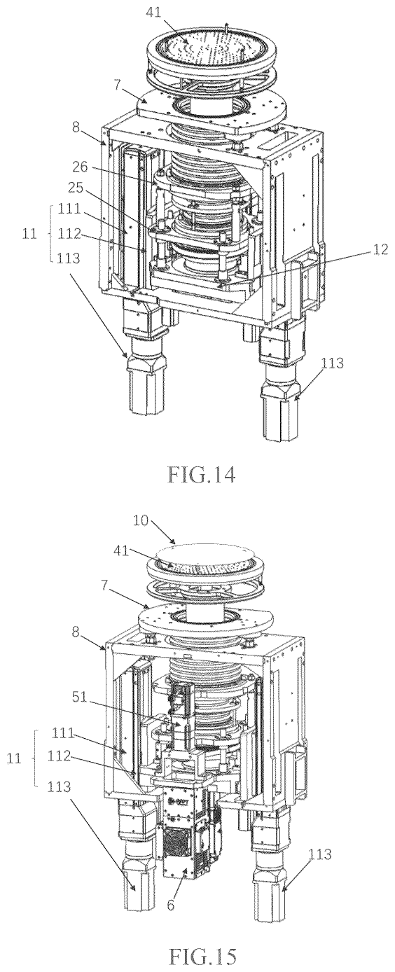

Referring to FIG. 13, the second embodiment provides a thin film deposition device, and compared with the first embodiment, the difference is that a supporting mechanism 3 comprises a heat reflective plate 32 provided on a guide ring platform 36.

The supporting mechanism 3 is provided with a heating plate 33 below a guide ring 31 for heating the guide ring 31. The heating tray 41 corresponds to an inner heating tray, the guide ring 31 corresponds to an outer heating tray, and the inner heating tray and the outer heating tray together form a heating region. When the wafer 10 is heated, there is a temperature difference between the temperature of the outer wall of the process chamber 9 and the heating region. In order to reduce the heat generated by the heating plate 33 (see FIG. 12) from being dissipated outside the heating region, in an alternative embodiment, the guide ring platform 36 is provided with a fan-shaped heat reflective plate 32. The heat reflective plate 32 is detachably disposed between the guide ring 31 and the guide ring platform 36. The heat reflective plate 32 can reflect part of the lost heat into the heating region to reduce the lost heat from the outer heating tray, so that the temperature of the central region and the edge region of the wafer 10 remains consistent. The heat reflective plate 32 is made of ceramic material.

Furthermore, the heat reflective plate 32 may be placed between adjacent connecting rods 35 (not shown in FIG. 13, referring to FIG. 1). Furthermore, the position of the heat reflective plate 32 is arranged according to the numerical value measured by the second temperature sensor 43 (not shown in FIG. 13, referring to FIG. 12).

### Embodiment 3

The device of the first embodiment adopts the design of a single module, and one side of the first-stage platform 12 is arranged on the first-stage driving unit 11. When the process chamber 9 is vacuumized, when the first-stage driving unit 11 on one side drives the first-stage platform 12 to ascend, the first-stage platform 12 is easily bent and inclined, thus affecting the levelness of the heating tray 41.

The thin film deposition device provided in the third embodiment adopts a dual-module design to solve the above-mentioned problems. Referring to FIGS. 14-16, in an alternative embodiment, the first-stage lifting mechanism comprises two first-stage driving units 11, and the two first-stage driving units 11 are respectively disposed on both sides (left and right sides in the figure) of the outer frame 8. The first-stage platform 12 has a U-shape when viewed from above. Both ends of the first-stage platform 12 are respectively arranged on the sliders 112 on both sides, the controller 100 drives the driving sources 113 on both sides to work synchronously, and the first-stage platform 12 ascends as a whole, effectively avoiding the situation that the first-stage platform 12 is bent and inclined.

The device further comprises a radio frequency generator 6, and the radio frequency generator 6 is connected to the controller 100. The radio frequency generator 6 has an on state and an off state, and the controller 100 is used to control the periodic turn on and off of the radio frequency generator 6. When the radio frequency generator 6 is in the on state, the process gas inside the process chamber 9 is excited to dissociate into plasma gas, and the plasma gas performs thin film deposition on the wafer 10. It should be noted that the radio frequency generator 6 can also be applied to the first embodiment.

When using the radio frequency generator 6, radio waves, electronic devices, or components using electricity may produce noise. In an alternative embodiment, a filter is used to reduce noise. The filter is arranged on the radio frequency generator 6, the radio frequency generator 6 is mounted on the first-stage platform 12, and the filter ascends and descends with the first-stage platform 12.

In summary, the above embodiments are merely used to describe the technical solutions of the present invention, and are not intended to limit the present invention. Although the present invention has been described in detail with reference to the aforementioned embodiments, those of ordinary skill in the art should understand that the technical solutions described in the aforementioned embodiments may still be modified or some technical features may be equivalently replaced. However, these modifications or substitutions do not deviate the essence of the corresponding technical solutions from the spirit and scope of the technical solutions of each embodiment of the present invention.

What is claimed is:

1. A thin film deposition device, comprising:
a heating mechanism (4), including a heating tray (41), used to carry and heat a wafer (10);
a supporting mechanism (3), including a guide ring (31) arranged around the heating tray (41) and a guide support shaft (34) connected to the guide ring (31);
a second-stage lifting mechanism (2), connected to the guide support shaft (34), used to drive the guide support shaft (34) and the guide ring (31) to ascend and descend, and enabling the guide ring (31) to be higher than the heating tray (41) when the guide ring (31) carries the wafer (10) to ascend;
a rotating mechanism (5), connected to the second-stage lifting mechanism (2), used to drive the guide ring (31) to rotate through the second-stage lifting mechanism (2);
a first-stage lifting mechanism (1), carrying the second-stage lifting mechanism (2), the rotating mechanism (5) and the heating mechanism (4), used to drive the rotating mechanism (5), the second-stage lifting mechanism (2) and the heating mechanism (4) to synchronously ascend and descend; and
a controller (100), used to control the first-stage lifting mechanism (1) to drive the rotating mechanism (5), the second-stage lifting mechanism (2), the supporting mechanism (3) and the heating mechanism (4) to ascend synchronously in the first thin film deposition step, and making the heating tray (41) and the guide ring (31) ascend to the height of carrying the wafer (10); used to control the second-stage lifting mechanism (2) to drive the guide ring (31) to carry the wafer (10) and continue to ascend in the second thin film deposition step, and after the rotating mechanism (5) is intermittently controlled to drive the guide ring (31) and the wafer (10) to rotate by a preset angle, controlling the second-stage lifting mechanism (2) to drive the guide ring (31) to descend to the height of the heating tray (41).

2. The thin film deposition device according to claim 1, wherein the heating mechanism (4) further comprises a tray shaft (44), one end of the tray shaft (44) is arranged on the heating tray (41), and the other end of the tray shaft (44) is connected to the first-stage lifting mechanism (1).

3. The thin film deposition device according to claim 2, wherein the supporting mechanism (3) further comprises connecting rods (35) and a guide ring platform (36), a plurality of connecting rods (35) are arranged between the guide ring (31) and the guide ring platform (36), the guide ring platform (36) is connected to the guide support shaft (34), and the tray shaft (44) is sleeved in the guide support shaft (34).

4. The thin film deposition device according to claim 2, wherein the first-stage lifting mechanism (1) comprises a first-stage driving unit (11) and a first-stage platform (12), and the first-stage platform (12) is arranged at the output end of the first-stage driving unit (11);
the second-stage lifting mechanism (2), the rotating mechanism (5) and the tray shaft (44) are arranged on the first-stage platform (12).

5. The thin film deposition device according to claim 4, wherein the first-stage driving unit (11) comprises a linear module (111), a slider (112) and a driving source (113), the slider (112) is movably mounted on the linear module (111), the first-stage platform (12) is mounted on the slider (112), and the driving source (113) is connected to the controller (100).

6. The thin film deposition device according to claim 5, wherein the first-stage driving unit (11) further comprises a speed reducer (114) disposed between the driving source (113) and the linear module (111).

7. The thin film deposition device according to claim 5, wherein the thin film deposition device further comprises a process chamber platform (7), an outer frame (8) and a process chamber (9);
the outer frame (8) is connected to the process chamber platform (7), and the process chamber platform (7) is fixedly connected to the process chamber (9);
the guide ring (31) and the heating tray (41) are both arranged in the process chamber (9), and one end of the tray shaft (44) extends downward to the first-stage platform (12) through the process chamber (9) and the process chamber platform (7);
the linear module (111) is arranged on the outer frame (8), and the driving source

(113) is connected to the linear module (111).

8. The thin film deposition device according to claim 7, wherein the second-stage lifting mechanism (2) comprises a second-stage driving unit (21), an upper bellows (22), a lower bellows (23), an upper magnetic fluid (24), a second-stage lower platform (25) and a second-stage upper platform (26);
the second-stage lower platform (25) and one side of the second-stage upper platform (26) are connected by a second support member (252), and the other side of the second-stage upper platform (26) is connected to the lower end of the upper bellows (22);
the second-stage driving unit (21) is used to drive the second-stage lower platform (25) to ascend, and the second-stage lower platform (25) is used to drive the second-stage upper platform (26) to ascend and compress the upper bellows (22);
the upper end of the lower bellows (23) is connected to the upper magnetic fluid (24), and the lower end of the lower bellows (23) is connected to the rotating mechanism (5);
the upper end of the upper bellows (22) is fixed to the process chamber platform (7), the upper magnetic fluid (24) is respectively connected to the guide support shaft (34) and the lower end of the upper bellows (22), the upper magnetic fluid (24) ascends together with the lower end of the upper bellows (22) and drives the guide support shaft (34), the guide ring (31) and the upper end of the lower bellows (23) to ascend.

9. The thin film deposition device according to claim 8, wherein the upper magnetic fluid (24) comprises an upper magnetic fluid inner shaft (241) and an upper magnetic fluid outer ring (242), and the upper magnetic fluid outer ring (242) is sleeved at the outer periphery of the upper magnetic fluid inner shaft (241);
the upper end of the upper magnetic fluid inner shaft (241) is connected to the guide support shaft (34), the upper magnetic fluid outer ring (242) is connected to the lower end of the upper bellows (22), and the upper end of the lower bellows (23) is connected to the lower end of the upper magnetic fluid inner shaft (241).

10. The thin film deposition device according to claim 8, wherein the second-stage lower platform (25) and the first-stage platform (12) are connected by a first support member (251), and when the first-stage driving unit (11) drives the first-stage platform (12) to ascend, the second-stage lower platform (25) ascends together with the first-stage platform (12) and drives the second-stage upper platform (26) to ascend to compress the upper bellows (22).

11. The thin film deposition device according to claim 9, wherein the rotating mechanism (5) comprises a rotation driving unit (51), a pulley (52) and a lower magnetic fluid (53);
the lower magnetic fluid (53) includes a lower magnetic fluid inner shaft (531) and a lower magnetic fluid outer ring (532), and the lower magnetic fluid outer ring (532) is sleeved at the outer periphery of the lower magnetic fluid inner shaft (531);
the lower magnetic fluid outer ring (532) is connected to the lower end of the lower bellows (23), and the lower magnetic fluid inner shaft (531) is connected to the first-stage platform (12);
the pulley (52) is sleeved on the lower magnetic fluid outer ring (532) for driving the lower magnetic fluid outer ring (532) to rotate, and the lower bellows (23), the upper magnetic fluid inner shaft (241), the guide support shaft (34) and the guide ring (31) rotate together with the lower magnetic fluid outer ring (532).

12. The thin film deposition device according to claim 7, wherein the thin film deposition device further comprises a first displacement sensor (81) and a second displacement sensor (82) both connected to the controller (100) and provided on the outer frame (8), the first displacement sensor (81) is used to monitor the moving distance of the first-stage platform (12), and the second displacement sensor (82) is used to monitor the moving distance of the second-stage lower platform (25).

13. The thin film deposition device according to claim 9, wherein the upper magnetic fluid outer ring (242) and the lower end of the upper bellows (22) are connected by a third flange (29);
the third flange (29) is provided with an N2 gas source interface (291), the third flange (29) and the upper magnetic fluid (24) are both provided with through holes, and the N2 gas source is blown into the first gap between the tray shaft (44) and the upper magnetic fluid (24) and the second gap between the tray shaft (44) and the guide support shaft (34) through the N2 gas source interface (291) and the through holes sequentially, and flows out to the outside of the process chamber (9).

14. The thin film deposition device according to claim 7, wherein one end of a plurality of connectors (71) on the process chamber platform (7) is connected to the bottom of the process chamber platform (7), the other end of the connectors (71) is connected to the outer frame (8), and the levelness of the outer frame (8) is adjusted when the position of the connectors (71) is adjusted.

15. The thin film deposition device according to claim 8, wherein the second-stage lifting mechanism (2) further comprises a second adjusting member (261) provided on the second-stage upper platform (26), and when the position of the second adjusting member (261) at the upper end of the second support member (252) is adjusted, the second-stage lower platform (25) and the second-stage upper platform (26) are parallel.

16. The thin film deposition device according to claim 4, wherein the tray shaft (44) comprises a basic shaft (441), a fixed seat (442) and an adapter shaft (443), an upper end of the basic shaft (441) is connected to the heating tray (41), two ends of the fixed seat (442) are respectively connected to the lower end of the basic shaft (441) and the upper end of the adapter shaft (443), and the lower end of the adapter shaft (443) is connected to the first platform (12);
a sealing ring is both provided at the connection between the fixed seat (442) and the basic shaft (441) and at the connection between the fixed seat (442) and the adapter shaft (443);
the inner cavities of the adapter shaft (443) and the fixed seat (442) are provided with a liquid inlet pipe (46) and a liquid outlet pipe (45), and the liquid inlet pipe (46) and the liquid outlet pipe (45) are communicated with each other.

17. The thin film deposition device according to claim 1, wherein after the first thin film deposition step is completed, (number of wafer rotations +1)*preset angle of each wafer rotation=360°.

18. The thin film deposition device according to claim 2, wherein the heating mechanism (4) further comprises a first temperature sensor (42) disposed in the inner cavity of the tray shaft (44), and an end of the first temperature sensor (42) is inserted into the inside of the heating tray (41);
the first temperature sensor (42) is connected to the controller (100), and the first temperature sensor (42) is used to measure the temperature value of the heating tray (41) and transmit the temperature value to the controller (100).

19. The thin film deposition device according to claim 1, wherein the supporting mechanism (3) further comprises a heating plate (33) disposed below the guide ring (31), the heating plate (33) has the same shape as the guide ring (31), the heating plate (33) is used to heat the guide ring (31) and thereby heat the edge region of the wafer (10).

20. The thin film deposition device according to claim 19, wherein the heating mechanism (4) further comprises a second temperature sensor (43) arranged on the guide ring (31), the second temperature sensor (43) is connected to the controller (100), and the second temperature sensor (43) is use to measure the temperature of the guide ring (31) and feed back to the controller (100).

21. The thin film deposition device according to claim 3, wherein the supporting mechanism (3) further comprises a fan-shaped heat reflective plate (32) on the guide ring platform (36), the heat reflective plate (32) is positioned between the guide ring (31) and the guide ring platform (36).

22. The thin film deposition device according to claim 21, wherein the material of the heat reflective plate (32) is ceramic material.

23. The thin film deposition device according to claim 7, wherein the first-stage lifting mechanism (1) comprises two first-stage driving units (11), the two first-stage driving units (11) are respectively arranged on both sides of the outer frame (8), both ends of the first-stage platform (12) are respectively arranged on the sliders (112) on both sides, and the controller drives the driving sources (113) on both sides to work synchronously.

24. The thin film deposition device according to claim 4, wherein the thin film deposition device further comprises a radio frequency generator (6) and a filter, the radio frequency generator (6) is connected to the controller (100), the filter is arranged on the radio frequency generator (6), and the radio frequency generator (6) is mounted on the first-stage platform (12).

25. The thin film deposition device according to claim 7, wherein the inside of the process chamber (9) comprises a counterweight plate (92), thimbles (93) and a support column (94), the support column (94) is fixed to the bottom of the process chamber (9), the thimbles (93) are arranged on the counterweight plate (92), and the counterweight plate (92) overlaps on the support column (94) by gravity;
the heating tray (41) is provided with accommodation holes, and the thimbles (93) move up and down in the accommodation holes for carrying the wafer (10).

26. The thin film deposition device according to claim 1, wherein in the first thin film deposition step, a first protrusion (311) of the guide ring (31) overlaps a second protrusion (411) of the heating tray (41).
